(19) United States
(12) Patent Application Publication
(10) Pub. No.: US 2024/0376627 A1
(43) Pub. Date: Nov. 14, 2024

(54) ELECTROPLATING APPARATUS

(71) Applicant: ACM RESEARCH (SHANGHAI), INC., Shanghai (CN)

(72) Inventors: Jian Wang, Shanghai (CN); Chen Wang, Shanghai (CN); Hongchao Yang, Shanghai (CN); Chenhua Lu, Shanghai (CN); Jiaqi Li, Shanghai (CN); Zhaowei Jia, Shanghai (CN); Ling Qin, Shanghai (CN); Hui Wang, Shanghai (CN)

(73) Assignee: ACM RESEARCH (SHANGHAI), INC., Shanghai (CN)

(21) Appl. No.: 18/691,994

(22) PCT Filed: Jul. 22, 2022
(86) PCT No.: PCT/CN2022/107509

§ 371 Date: Mar. 14, 2024

(30) Foreign Application Priority Data
Sep. 14, 2021 (CN) 2021111073167.7

(51) Int. Cl. C25D 21/10; C25D 17/00

(52) U.S. Cl. CPC C25D 21/10; C25D 17/001

(57) ABSTRACT

An electroplating device includes a process chamber, a paddle plate and a driving mechanism. The driving mechanism is used for driving the paddle plate to move back and forth to make the paddle plate stir the electroplating solution in the process chamber when a substrate is electroplated. The electroplating device further includes a cleaning assembly and a connecting bracket. The cleaning assembly is used for spraying a cleaning solution onto the electroplated substrate. One end of the connecting bracket is connected to the paddle plate, and the other end of the connecting bracket is connected to the driving mechanism, and the driving mechanism drives the paddle plate to move back and forth via the connecting bracket. The connecting bracket is opened with a hollowed-out area, and the cleaning solution sprayed onto the substrate is collected after passing through the hollowed-out area.

### BACKGROUND OF THE INVENTION

### 1. Field of the Invention

The present invention relates to the field of semiconductor equipment, and more particularly relates to an electroplating device.

### 2. The Related Art

In the electroplating process, the stability of the composition of the electroplating solution is particularly important to the reliability of the electroplated products. After electroplating the substrate, it is necessary to clean the surface of the substrate to clean the electroplating solution on the surface of the substrate to prevent the surface of the substrate from being eroded and oxidized and to prevent the electroplating solution on the surface of the substrate from going into the next electroplating process, which affects the next electroplating process.

In order to increase the electroplating rate, a paddle plate is usually used to stir the electroplating solution, and the drive mechanism drives the paddle plate to move back and forth via a connecting bracket. For a connecting bracket in the prior art, the shape of the connecting bracket is a solid plate, and it is only considered that the connecting bracket can be fixedly connected to the paddle plate, so that the drive mechanism can drive the paddle plate to move back and forth by the connecting bracket. Therefore, in the process of cleaning the substrate by a cleaning assembly, the cleaning solution sprayed by the cleaning assembly will be sprayed to the connecting bracket and back splash and fall into the electroplating solution, so that the electroplating solution will be diluted, causing the next batch of substrates to fail reliability tests and be scrapped after the electroplating process is completed in the diluted electroplating solution.

### SUMMARY

An object of the present invention is to solve the problem of dilution of electroplating solution by cleaning solution within an electroplating device in the prior art. Accordingly, the present invention provides an electroplating device having the advantage of avoiding dilution of the electroplating solution by the cleaning solution within the electroplating device.

In order to achieve the above object, one embodiment of the present invention provides an electroplating device comprising a process chamber, a paddle plate and a driving mechanism for driving the paddle plate to move back and forth to make the paddle plate stir the electroplating solution in the process chamber when the substrate is electroplated, the electroplating device further comprising:

a cleaning assembly for spraying a cleaning solution onto the electroplated substrate;

a connecting bracket, one end of the connecting bracket being connected to the paddle plate, and the other end of the connecting bracket being connected to the driving mechanism, and the driving mechanism driving the paddle plate to move back and forth via the connecting bracket; wherein the connecting bracket is opened with a hollowed-out area, and the cleaning solution sprayed onto the substrate is collected after passing through the hollowed-out area.

With the above technical solution, by providing the hollowed-out area on the connecting bracket, when the cleaning assembly sprays the cleaning solution on the electroplated substrate for cleaning, the substrate rotates so that the cleaning solution sprayed onto the substrate is thrown away from the substrate, and the cleaning solution thrown away from the substrate is collected after passing through the hollowed-out area, thereby preventing the cleaning solution from being thrown onto the connecting bracket to be back-splashed and fall into the electroplating solution, diluting the electroplating solution. Thus, the electroplating device has the advantage of avoiding dilution of the electroplating solution.

Further, another embodiment of the present invention provides an electroplating device, the connecting bracket comprising a support portion, a connection portion and a fixation portion, the connection portion connecting the support portion and the fixation portion, the support portion being opened with the hollowed-out area, the fixation portion connecting the paddle plate, the fixation portion including one end of the connecting bracket, and the support portion including the other end of the connecting bracket.

Further, another embodiment of the present invention provides an electroplating device, the hollowed-out area of the connecting bracket having at least one stiffener bridged within the hollowed-out area.

With the above technical solution, the rigidity of the connecting bracket can be enhanced by providing the at least one stiffener in the hollowed-out area.

Further, another embodiment of the present invention provides an electroplating device, the shape of the hollowed-out area is a rectangle, with a stiffener bridged between two opposite sides of the rectangle to divide the hollowed-out area into a first hollowed-out area and a second hollowed-out area.

Further, another embodiment of the present invention provides an electroplating device, the first hollowed-out area being provided with at least one first stiffener and/or the second hollowed-out area being provided with at least one second stiffener.

Further, another embodiment of the present invention provides an electroplating device, the stiffener and four sides of the rectangle are provided with chamfers.

Further, another embodiment of the present invention provides an electroplating device, the stiffener is a cylindrical shape.

Further, another embodiment of the present invention provides an electroplating device, the process chamber having a shroud, the shroud having a top, a middle and a bottom in turn, the shroud having a collection groove and a blocking ring, the collection groove being connected to the blocking ring and both the collection groove and the blocking ring being close to the bottom of the shroud, and the connecting bracket extending through the shroud in a height direction of the shroud;

when the cleaning assembly sprays the cleaning solution to the substrate to clean the substrate, the cleaning solution on the substrate is thrown into the collection groove through the hollowed-out area.

With the above technical solution, by providing the connecting bracket extending through the shroud and allowing the cleaning solution to pass through the hollowed-out area of the connecting bracket and be thrown into the collection groove, the cleaning solution thrown toward the connecting bracket can pass through the hollowed-out area and fall into the collection groove in the process of the cleaning assembly spraying the cleaning solution toward the rotating substrate to clean the substrate, thereby effectively improving the problem of the cleaning solution splashing back into the electroplating solution, resulting in the dilution of the electroplating solution.

Further, another embodiment of the present invention provides an electroplating device, wherein an upper channel is opened at the top of the shroud, a lower channel is opened at the bottom of the shroud, wherein the lower channel is close to a location where the collection groove is connected to the blocking ring, wherein one end of the connecting bracket passes through the lower channel to connect to the paddle plate, and the other end of the connecting bracket passes through the upper channel to connect to the driving mechanism; wherein in the direction of movement of the paddle plate, the width of the upper channel and the lower channel is greater than the width of the connecting bracket; the shroud is further provided with a retaining weir, the retaining weir extending towards the paddle plate from a side of the lower channel away from the collection groove, the two sides of the retaining weir being connected to the blocking ring, and the top surface of the retaining weir being higher than the top surface of the blocking ring.

With the above technical solution, by providing the retaining weir, and the top surface of the retaining weir is higher than the top surface of the blocking ring, the cleaning solution falling to the top surface of the retaining weir is able to flow out from both sides of the retaining weir, and flow through the blocking ring to the collection groove.

Further, another embodiment of the present invention provides an electroplating device, chamfers provided on both sides of the retaining weir near its top surface.

Further, another embodiment of the present invention provides an electroplating device, the top of the shroud comprising a first sidewall and a second sidewall, an angle being formed between the second sidewall and the first sidewall, and an angle also being formed between the second sidewall and the middle of the shroud, the second sidewall being tilted with respect to the horizontal plane, the angle of tilt ranging from 15° to 45°; wherein the upper channel is opened on the second sidewall of the shroud.

With the above technical solution, an angle is formed between the second sidewall and the first sidewall at the top of the shroud, and an angle is formed between the second sidewall and the middle of the shroud, and the second sidewall is tilted at a certain angle with respect to the horizontal plane, so that the cleaning solution thrown away from the surface of the substrate arrives at the shroud and then splashes back and falls into the electroplating solution, so as to further improve the problem of dilution of the electroplating solution by the cleaning solution.

Further, another embodiment of the present invention provides an electroplating device, comprising two connecting brackets, the two connecting brackets being disposed opposite each other.

With the above technical solution, the paddle plate can be driven to move back and forth more stably by setting up two connecting brackets.

Further, another embodiment of the present invention provides an electroplating device, the cleaning assembly being obliquely disposed at the middle of the shroud, the cleaning assembly comprising a nozzle and a connection tube, one end of the connection tube being fixed at the middle of the shroud, the nozzle being fixed at the other end of the connection tube, and the cleaning solution being sprayed out from the nozzle.

Further, another embodiment of the present invention provides an electroplating device, the nozzle being tilted with respect to the horizontal plane at a tilt angle ranging from 5° to 60°. The distance between the nozzle and the vertical centerline of the substrate being in the range of 180 mm to 200 mm. The vertical distance between the nozzle and the substrate is in the range of 10 mm to 30 mm in the height direction of the shroud.

With the above technical solution, the parameters design of the cleaning assembly can ensure that the distance of the cleaning solution sprayed by the nozzle to the substrate, as well as the area of the cleaning solution sprayed on the substrate, are controlled within a specified range.

Further, another embodiment of the present invention provides an electroplating device, the cleaning assembly being configured such that the distance between the position where the cleaning solution sprayed by the nozzle is sprayed onto the substrate and the nozzle is adjustable.

With the above technical solution, the distance between the position where the cleaning solution sprayed by the nozzle of the cleaning assembly is sprayed onto the substrate and the nozzle is adjustable, which can avoid the distance being too large, and if this distance is too large, the cleaning solution sprayed from the nozzle will be sprayed onto the chuck area of the clamping substrate, causing back splash, resulting in a large amount of falling cleaning solution, causing the electroplating solution to be diluted by the falling cleaning solution.

Further, another embodiment of the present invention provides an electroplating device, the adjustable range of the distance between the position where the cleaning solution sprayed from the nozzle reaches the substrate and the nozzle is 150 mm˜180 mm.

Further, another embodiment of the present invention provides an electroplating device, the blocking ring being tilted with respect to the horizontal plane and a tilt angle ranging from 10°-45°.

With the above technical solution, by designing the tilt angle of the blocking ring, which in turn has a corresponding tilt height, on the one hand, the cleaning solution that is thrown away from the surface of the substrate passes through the blocking ring and falls into the collection groove, which avoids the cleaning solution from falling into the electroplating solution; and on the other hand, the electroplating solution underneath is blocked from splashing into the collection groove.

Other features of the present invention and corresponding beneficial effects are set forth in later portions of the specification, and it should be understood that at least some of the beneficial effects become apparent from the specification of the present invention.

### BRIEF DESCRIPTION OF THE DRAWINGS

FIG. 1 illustrates a sectional view of an electroplating device provided by the present invention;

FIG. 2 illustrates a perspective view of a connecting bracket in the electroplating device provided by the present invention;

FIG. 3 illustrates a partially enlarged view of part A in FIG. 2;

FIG. 4 illustrates a sectional view of another view of the electroplating device provided by the present invention;

FIG. 5 illustrates a schematic view of a partial structure of the electroplating device provided by the present invention;

FIG. 6 illustrates a perspective view of a shroud portion of the electroplating device provided by the present invention;

FIG. 7 illustrates a schematic view of a partial cross-section of the shroud in the electroplating device provided by the present invention; and

FIG. 8 illustrates a sectional view of the shroud portion of the electroplating device provided by the present invention.

### DETAILED DESCRIPTION OF EMBODIMENTS

The implementation of the present invention will be illustrated by specific examples below, and those skilled in the art can easily understand other advantages and effects of the present invention from the content disclosed in this specification. Although the description of the present invention will be presented in conjunction with a preferred embodiment, it does not mean that the features of the present invention are limited to this embodiment. On the contrary, the purpose of introducing the present invention in conjunction with the embodiments is to cover other options or modifications that may be extended based on the claims of the present invention. The following description contains numerous specific details in order to provide a thorough understanding of the present invention. The present invention may also be practiced without these details. Also, some specific details will be omitted from the description in order to avoid confusion or obscuring the gist of the present invention. It should be noted that, in the case of no conflict, the embodiments of the present invention and the features in the embodiments can be combined with each other.

It should be noted that in this specification, similar numerals and letters denote similar items in the following drawings, therefore, once an item is defined in one drawing, it does not need to be defined and explained in subsequent drawings.

The technical solutions of the present invention will be clearly and completely described below in conjunction with the accompanying drawings. Apparently, the described embodiments are some of the embodiments of the present invention, but not all embodiments. Based on the embodiments of the present invention, all other embodiments obtained by persons of ordinary skill in the art without making creative efforts belong to the protection scope of the present invention.

In the description of the present invention, it should be noted that the terms “center”, “upper”, “lower”, “left”, “right”, “vertical”, “horizontal”, “inner”, “outer” etc. indicate orientation or positional relationship that is based on the orientation or positional relationship shown in the drawings, and is only for the convenience of describing the present invention and simplifying the description, rather than indicating or implying that the referred device or element must have a specific orientation, or in a specific orientation. construction and operation, therefore, should not be construed as limiting the present invention. In addition, the terms “first”, “second”, and “third” are used for descriptive purposes only, and should not be construed as indicating or implying relative importance.

In the description of the present invention, it should be noted that unless otherwise specified and limited, the terms “installation”, “connection” should be understood in a broad sense, for example, it can be a fixed connection or a detachable connection, or integrally connected; it can be mechanically connected or electrically connected; it can be directly connected or indirectly connected through an intermediary, and it can be the internal communication of two components. Those of ordinary skill in the art can understand the specific meanings of the above terms in the present invention in specific situations.

In order to make the purpose, technical solution and advantages of the present invention be clearer, the following will further describe the implementation of the present invention in detail in conjunction with the accompanying drawings.

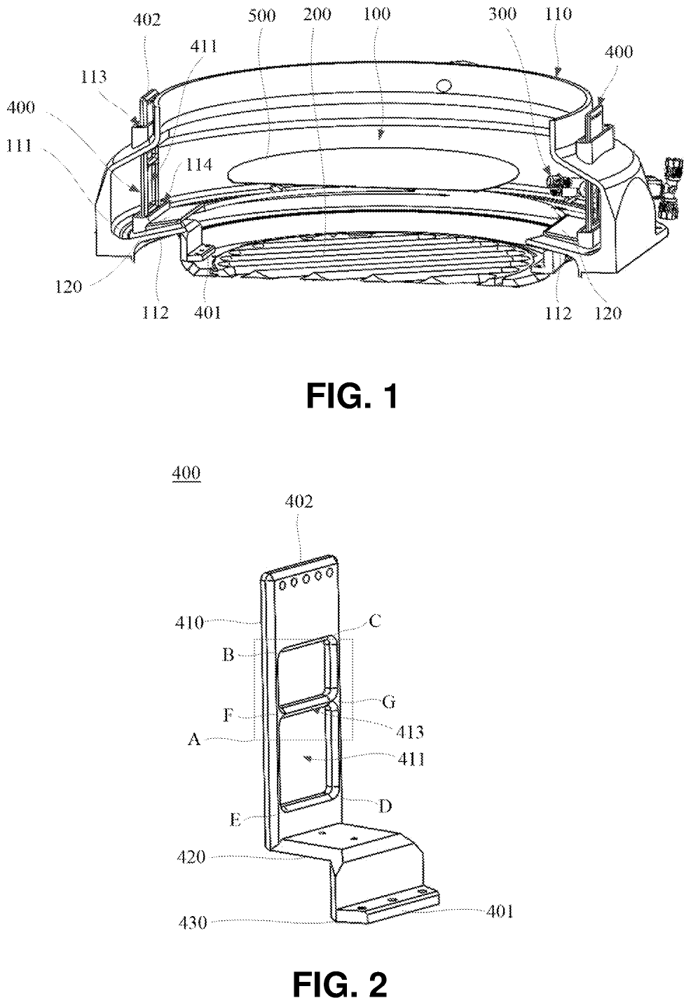

Referring to FIG. 1, the present invention provides an electroplating device comprising a process chamber 100, a paddle plate 200 disposed within the process chamber 100, and a driving mechanism (not shown in the figure). The driving mechanism is used to drive the paddle plate 200 to move back and forth, such that the paddle plate 200 stirs the electroplating solution within the process chamber 100.

The electroplating device further includes a cleaning assembly 300 and a connecting bracket 400. The cleaning assembly 300 is disposed above the paddle plate 200 for spraying a cleaning solution 330 onto the electroplated substrate 500.

One end 401 of the connecting bracket 400 is connected to the paddle plate 200, and the other end 402 of the connecting bracket 400 is connected to the driving mechanism, and the driving mechanism drives the paddle plate 200 to move back and forth via the connecting bracket 400; wherein the connecting bracket 400 is opened with a hollowed-out area 411, and the cleaning solution 330 sprayed onto the substrate 500 is collected after passing through the hollowed-out area 411, and the cleaning solution 330 may be deionized water.

The electroplating device further comprises a chuck, a rotation axis, a rotation driver and a lifting mechanism (none of which are shown in the figures). The chuck is used to clamp the substrate 500. The rotation axis connects the chuck and the rotation driver. The rotation driver drives the rotation axis to rotate, and the chuck rotates with the rotation axis. The rotation driver is connected to the lifting mechanism, and the lifting mechanism is used to realize the substrate 500 to carry out a lifting movement.

When the electroplating process is performed, the lifting mechanism makes the substrate 500 tilt at a certain angle and face downwards enter the electroplating solution of the process chamber 100 via the chuck, and after the substrate 500 is completely immersed in the electroplating solution the substrate 500 is kept horizontally to perform the electroplating process on the front side of the substrate 500. After completing the electroplating process, the lifting mechanism raises the substrate 500 to a certain cleaning position, and the cleaning assembly 300 sprays the cleaning solution 330 to the front side of the substrate 500 in order to remove the plating solution, and at the same time, the rotation driver drives the chuck to rotate via the rotation axis, causing the cleaning solution 330 sprayed onto the substrate 500 to be thrown away from the substrate 500, and the cleaning solution 330 thrown away from the substrate 500 passes through the hollowed-out area 411 and then is collected, which is capable of preventing the cleaning solution 330 thrown towards the connecting bracket 400 from splashing back and falling into the electroplating solution, and thus avoiding the electroplating solution being diluted.

Referring to FIG. 2, the connecting bracket 400 includes a support portion 410, a connection portion 420 and a fixation portion 430. The connection portion 420 connects the support portion 410 and the fixation portion 430. The support portion 410 is opened with the hollowed-out area 411. The fixation portion 430 connects to the paddle plate 200. The fixation portion 430 contains one end 401 of the connecting bracket 400, and the support portion 410 contains the other end 402 of the connecting bracket 400. In the embodiment, the connection portion 420 is disposed horizontally, the support portion 410 is perpendicular or approximately perpendicular to the connection portion 420, and the fixation portion 430 is perpendicular or approximately perpendicular to the connection portion 420 and extends away from the support portion 410 to form the end 401 of the connecting bracket 400.

Referring to FIG. 2, the hollowed-out area 411 provided on the support portion 410 is substantially rectangular in shape and has four vertices B, C, D, E. In order to enhance the rigidity of the support portion 410, a stiffener 413 is bridged between two opposite sides of the rectangle. The stiffener 413 may divide the rectangle into two squares. For example, a first hollowed-out area surrounded by vertices B, C, G, F and a second hollowed-out area surrounded by vertices F, G, D, E.

In other alternative embodiments, two stiffeners 413 may also be bridged between two opposite sides of the rectangle to divide the rectangle into three squares. The present invention does not limit the number of stiffeners 413.

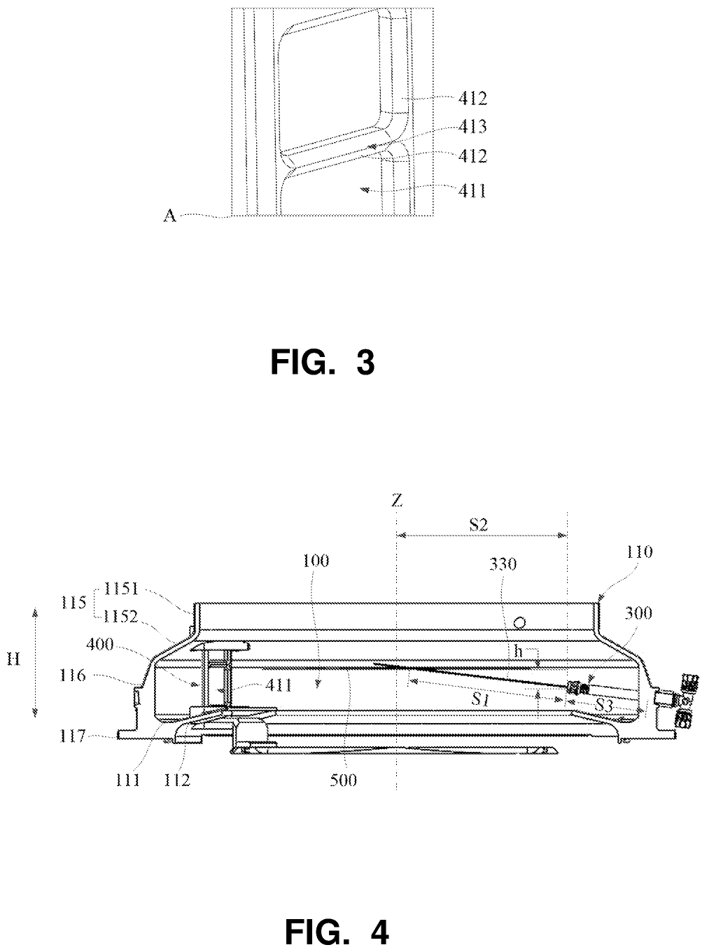

Combining FIGS. 2 and 3, the stiffener 413 and each of the four sides of the rectangle are formed with a chamfer 412, and the angle of the chamfer 412 may be 45°, and the shape of the stiffener 413 may be prismatic. The chamfers 412 can reduce the contact area of the cleaning solution 330 and the support portion 410. In other alternative embodiments, the shape of the stiffener 413 can be cylindrical to further reduce the contact area of the stiffener 413 and the cleaning solution 330.

It is understood by those skilled in the art that in other alternative embodiments, the stiffener 413 may be set between vertices B and D, or between vertices C and E, which also achieves the same effect of enhancing the rigidity of the support portion 410, and thereby enhancing the rigidity of the connecting bracket 400.

Alternatively, in the case of having the stiffener 413, a first stiffener (not shown in the figures) may be set between the vertex B and the vertex G, or/and between the vertex C and the vertex F of the first hollowed-out area; and/or, in the case of having the stiffener 413, a second stiffener (not shown in the figures) may be set between the vertex E and the vertex G, or/and between the vertex D and the vertex F of the second hollowed-out area. In the embodiment, the structure of the first stiffener and/or the second stiffener is the same as the structure of the stiffener 413 described above and will not be repeated herein.

The outer edge of the support portion 410 may be an arc surface, and the inner edge of the support portion 410 (at a location on the connecting bracket 400 adjacent to the hollowed-out area 411) may also be an arc surface. Portions of the connecting bracket 400 located between vertex B and vertex F, between vertex C and vertex G, between vertex E and vertex F, and between vertex D and vertex G may be cylindrical to reduce the contact area of the connecting bracket 400 and the cleaning solution 330. The outer edge of the support portion 410 may also be prismatic.

It is understood by those skilled in the art that in other alternative embodiments, the shape of the hollowed-out area 411 may also be circular, triangular, or polygonal, and it is sufficient as long as the cleaning solution 330 can pass through the hollowed-out area 411 to solve the problem of the electroplating solution being diluted, and the embodiment does not make a specific limitation on the shape of the hollowed-out area 411.

Combining FIGS. 1 and 4, the process chamber 100 has a shroud 110. The shroud 110 has a top 115, a middle 116, and a bottom 117 in turn. The shroud 110 has a connected collection groove 111 and a blocking ring 112. The collection groove 111 and the blocking ring 112 are both near the bottom 117 of the shroud 110, and the connecting bracket 400 extends through the shroud 110 in the height direction H of the shroud 110. The connection portion 420 of the connecting bracket 400 is located below the blocking ring 112. When the cleaning assembly 300 sprays the cleaning solution 330, the cleaning solution 330 thrown away from the substrate 500 passes through the hollowed-out area 411 and falls into the collection groove 111 to be collected.

In the embodiment, because the connecting bracket 400 extends through the shroud 110 and the connecting bracket 400 is configured to allow the cleaning solution 330 to pass through the hollowed-out area 411 and throw into the collection groove 111, so the cleaning assembly 300 sprays the cleaning solution 330 to the rotating substrate 500 during the cleaning process, the cleaning solution 330 thrown towards the connecting bracket 400 is able to pass through the hollowed-out area 411 and fall into the collection groove 111, which effectively improves the problem of the cleaning solution 330 falling into the electroplating solution that causes the electroplating solution to be diluted.

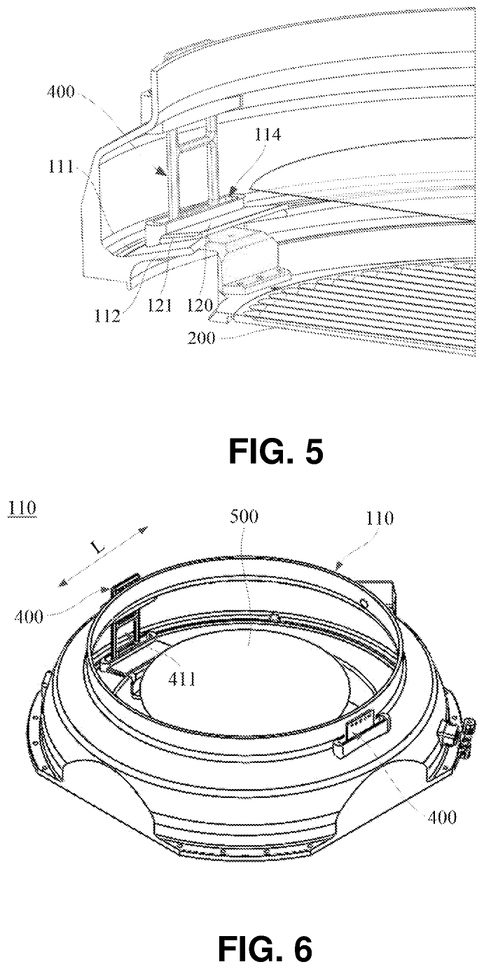

Combining FIGS. 1, 5, and 6, an upper channel 113 is opened at the top 115 of the shroud 110, and a lower channel 114 is opened at the bottom 117 of the shroud 110. The lower channel 114 is close to the location where the collection groove 111 is connected to the blocking ring 112. The end 401 of the connecting bracket 400 passes through the lower channel 114 to connect the paddle plate 200, and the other end 402 of the connecting bracket 400 passes through the upper channel 113 to connect the driving mechanism.

Wherein, in the movement direction L of the paddle plate 200, the width of the upper channel 113 and the width of the lower channel 114 are larger than the width of the connecting bracket 400, for the purpose of allowing the driving mechanism to drive the connecting bracket 400 to be able to move horizontally, and the paddle plate 200 moves horizontally together with the connecting bracket 400. In the embodiment, the driving mechanism is a motor, and the movement direction L of the paddle plate 200 is perpendicular to the direction of the vertical axis of the process chamber 100.

Since the cleaning solution 330 being thrown away from the substrate 500 will splash back after contacting the portion of the support portion 410 except for the hollowed-out area 411, the shroud 110 is also provided with a retaining weir 120. The retaining weir 120 extends toward the paddle plate 200 from the side of the lower channel 114 away from the collection groove 111, and both sides of the retaining weir 120 are connected to the blocking ring 112. The top surface of the retaining weir 120 is higher than the top surface of the blocking ring 112. Specifically, the retaining weir 120 is located directly above the connection portion 420 and covers the connection portion 420. The top surface of the retaining weir 120 is designed to be higher than the top surface of the blocking ring 112, so that the cleaning solution 330 flows out from the sides of the retaining weir 120 after back splashing to the top surface of the retaining weir 120, and then flows through the blocking ring 112 to the collection groove 111. The two sides of the retaining weir 120 may also be provided with chamfers 121 near the top surface to facilitate the cleaning solution 330 on the top surface to flow through the chamfers 121 to the collection groove 111.

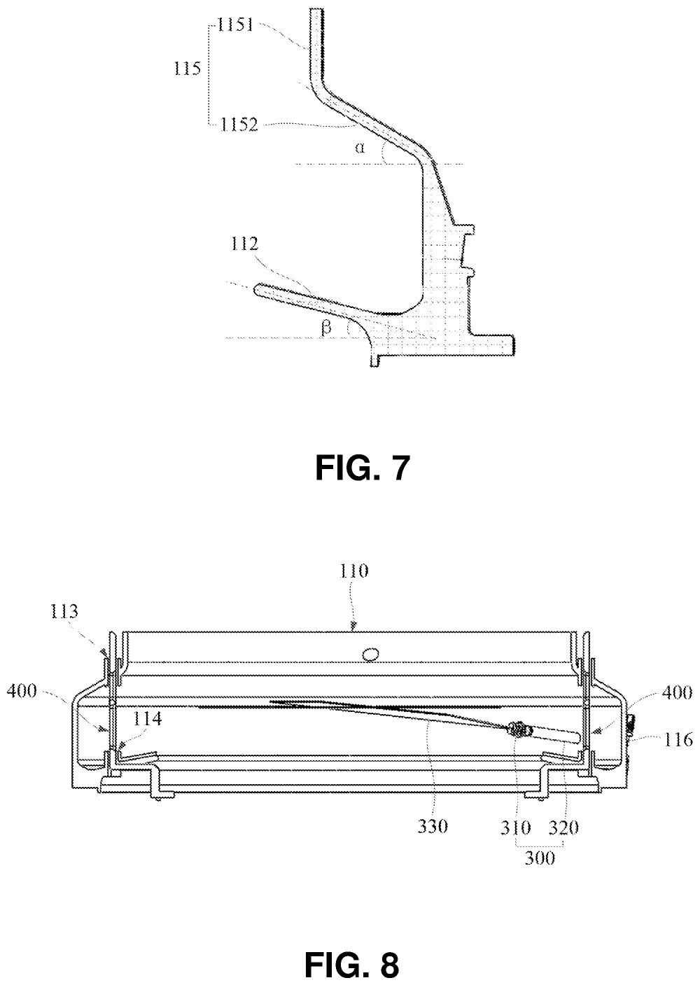

Combining FIGS. 4 and 7, the top 115 of the shroud 110 includes a first sidewall 1151 and a second sidewall 1152. An angle is formed between the second sidewall 1152 and the first sidewall 1151, and an angle is formed between the second sidewall 1152 and the middle 116 of the shroud 110. The second sidewall 1152 is tilted with respect to a horizontal plane, and the tilt angle α ranges from 15° to 45°. The upper channel 113 is provided on the second sidewall 1152 of the shroud 110. In the embodiment, the tilt angle α is 30° and the cross-section of the second sidewall 1152 is slope-shaped.

It is understood by those skilled in the art that in other alternative embodiments, the cross-section of the second sidewall 1152 may also be curved, which can achieve the effect of preventing the splashing back of cleaning solution 330.

In the embodiment, by setting an angle between the second sidewall 1152 of the top 115 of the shroud 110 and the first sidewall 1151, and setting an angle between the second sidewall 1152 of the top 115 of the shroud 110 and the middle 116 of the shroud 110, and tilting the second sidewall 1152 at a certain angle with respect to the horizontal plane, it can avoid that the cleaning solution 330 thrown away from the surface of the substrate 500 arrives at the shroud 110 and then splashes back to fall into the electroplating solution, so as to further improve the problem of the dilution of the electroplating solution by the cleaning solution 330.

In addition, the blocking ring 112 is tilted with respect to the horizontal plane, and the tilt angle β is in the range of 10° to 45°. In the embodiment, by designing the tilt angle β of the blocking ring 112, which in turn has a corresponding tilt height, on the one hand, the cleaning solution 330 that is thrown away from the surface of the substrate 500 passes through the blocking ring 112 and falls into the collection groove 111, which avoids the cleaning solution 330 from falling into the electroplating solution; and on the other hand, the electroplating solution underneath is blocked from splashing into the collection groove 111.

Combining FIGS. 1 and 8, the electroplating device includes two connecting brackets 400, and the two connecting brackets 400 are disposed opposite to each other. By providing the two connecting brackets 400, the paddle plate 200 can be driven to move back and forth more stably. In the embodiment, one of the two connecting brackets 400 is directly connected to the driving mechanism, called the active connecting bracket, and the other connecting bracket 400 is indirectly connected to the driving mechanism by the active connecting bracket, called the follower connecting bracket, wherein the driving mechanism drives the active connecting bracket to move back and forth, and the follower connecting bracket moves back and forth along with the active connecting bracket.

It is understood by those skilled in the art that in alternative other embodiments, the two connecting brackets 400 may be active connecting brackets. Moreover, the electroplating device includes, but is not limited to, two connecting brackets 400, for example, including four connecting brackets 400, two by two oppositely disposed on both sides of the paddle plate 200, wherein more than one of the connecting brackets 400 may be active connecting brackets and the rest are follower connecting brackets, with the specific setup being based on the actual process requirements.

Combining FIGS. 4 and 8, the cleaning assembly 300 is disposed at an inclined angle at the middle 116 of the shroud 110. The cleaning assembly 300 includes a nozzle 310 and a connection tube 320. One end of the connection tube 320 is fixed at the middle 116 of the shroud 110, and the nozzle 310 is fixed to the other end of the connection tube 320.

Alternatively, the connection tube 320 is configured to include a fixed tube (not shown in the figures) and a movable tube (not shown in the figures), and the fixed tube and the movable tube are interconnected. One end of the fixed tube is fixed at the middle 116 of the shroud 110. One end of the movable tube is rotatably connected to the other end of the fixed tube, and the nozzle 310 is fixed to the other end of the movable tube. That is, the distance S1 between the position where the cleaning solution 330 is sprayed onto the substrate 500 and the nozzle 310 is adjustable. Wherein, one end of the fixed tube is one end of the connection tube 320, and the other end of the movable tube is the other end of the connection tube 320.

In the case that the height position of the substrate 500 remains unchanged, the distance S1 described above is changed by rotating the movable tube in order to adjust the height of the cleaning solution 330 sprayed by the nozzle 310, thereby controlling the distance S1 to be within a prescribed range, so that a good cleaning effect is realized in the area of the cleaning solution 330 sprayed on the substrate 500.

The adjustable range of the above distance S1 is 150 mm to 180 mm to avoid this distance S1 being too large. If this distance S1 is too large, the cleaning solution 330 sprayed from the nozzle 310 will be sprayed onto the chuck area of the clamping substrate 500, causing splash back, resulting in a large amount of falling cleaning solution, causing the electroplating solution to be diluted by the falling cleaning solution.

It is understood by those skilled in the art that in other alternative embodiments, the movable tube may also be telescopically fixed to the other end of the fixed tube to adjust the movable tube along the length of the connection tube 320, and thus the distance S1 is adjusted in the case that the height position of the substrate 500 remains unchanged.

In addition, the adjustment of the above distance S1 can also be realized by lifting and lowering the substrate 500 by the lifting mechanism to change the height position at which the substrate 500 is located, in the case that the cleaning assembly 300 is fixed.

Further, in combination with FIGS. 4 and 8, the tilt angle of the nozzle 310 inclined relative to the horizontal plane ranges from 5° to 60°. The distance S2 between the nozzle 310 and the vertical centerline Z of the substrate 500 is in the range of 180 mm to 200 mm, and the vertical distance h between the nozzle 310 and the substrate 500 is in the range of 10 mm to 30 mm in the height direction H of the shroud 110. In the embodiment, the length S3 of the cleaning assembly 300 within the shroud 110 is in the range of 70 mm˜120 mm, and the specific value of this length S3 is set according to the actual situation of the distance S2.

In the embodiment, the above parameters of the cleaning assembly 300 are designed to ensure that the distance of the cleaning solution 330 sprayed by the nozzle 310 to the substrate 500, and the area of the cleaning solution 330 sprayed on the substrate 500 are controlled within a specified range.

Finally, it should be noted that the above embodiments are only used to illustrate the technical solutions of the present invention, not to limit them; although the present invention has been described in detail with reference to the foregoing embodiments, a person of ordinary skill in the art should understand that it is still possible to make modifications to the technical solutions described in the foregoing embodiments, or to make equivalent substitutions for some or all of the technical features therein; and such modifications or substitutions do not take the essence of the corresponding technical solutions out of the scope of the technical solutions of the embodiments of the present invention.

1. An electroplating device, comprising a process chamber, a paddle plate and a driving mechanism, the driving mechanism for driving the paddle plate to move back and forth to make the paddle plate stir the electroplating solution in the process chamber when a substrate is electroplated, the electroplating device further comprising:
a cleaning assembly for spraying a cleaning solution onto the electroplated substrate;
a connecting bracket, wherein one end of the connecting bracket is connected to the paddle plate, and the other end of the connecting bracket is connected to the driving mechanism, and the driving mechanism drives the paddle plate to move back and forth via the connecting bracket;
wherein the connecting bracket is opened with a hollowed-out area, and the cleaning solution sprayed onto the substrate is collected after passing through the hollowed-out area.

2. The electroplating device according to claim 1, wherein the connecting bracket comprises a support portion, a connection portion and a fixation portion, the connection portion connecting the support portion and the fixation portion, the support portion being opened with the hollowed-out area, the fixation portion connecting the paddle plate, the fixation portion including one end of the connecting bracket, and the support portion including the other end of the connecting bracket.

3. The electroplating device according to claim 1, wherein the hollowed-out area of the connecting bracket has at least one stiffener bridged within the hollowed-out area.

4. The electroplating device according to claim 3, wherein the shape of the hollowed-out area is a rectangle, with a stiffener bridged between two opposite sides of the rectangle to divide the hollowed-out area into a first hollowed-out area and a second hollowed-out area.

5. The electroplating device according to claim 4, wherein the first hollowed-out area is provided with at least one first stiffener and/or the second hollowed-out area is provided with at least one second stiffener.

6. The electroplating device according to claim 4, wherein the stiffener and four sides of the rectangle are provided with chamfers.

7. The electroplating device according to claim 3, wherein the shape of the stiffener is cylindrical.

8. The electroplating device according to claim 1, wherein the process chamber has a shroud, the shroud having in turn a top, a middle and a bottom, the shroud having a collection groove and a blocking ring, the collection groove being connected to the blocking ring and both being close to the bottom of the shroud, and the connecting bracket extending through the shroud in the height direction of the shroud;
when the cleaning assembly sprays the cleaning solution to the substrate to clean the substrate, the cleaning solution on the substrate passes through the hollowed-out area and is thrown into the collection groove.

9. The electroplating device according to claim 8, wherein an upper channel is opened at the top of the shroud, and a lower channel is opened at the bottom of the shroud, wherein the lower channel is close to a location where the collection groove is connected to the blocking ring, wherein one end of the connecting bracket passes through the lower channel to connect to the paddle plate, and the other end of the connecting bracket passes through the upper channel to connect to the driving mechanism;
wherein in the direction of movement of the paddle plate, the width of both the upper channel and the lower channel are greater than the width of the connecting bracket;
wherein the shroud is further provided with a retaining weir, the retaining weir extending towards the paddle plate from a side of the lower channel away from the collection groove, the two sides of the retaining weir being connected to the blocking ring, the top surface of the retaining weir being higher than the top surface of the blocking ring.

10. The electroplating device according to claim 9, wherein chamfers are provided on both sides of the retaining weir at a location near its top surface.

11. The electroplating device according to claim 9, wherein the top of the shroud comprises a first sidewall and a second sidewall, an angle being formed between the second sidewall and the first sidewall, and an angle also being formed between the second sidewall and the middle of the shroud, the second sidewall being tilted with respect to the horizontal plane, and a tilt angle ranging from 15° to 45°;
wherein the upper channel is opened on the second sidewall of the shroud.

12. The electroplating device according to claim 1, wherein the electroplating device comprises two connecting brackets, the two connecting brackets being disposed opposite each other.

13. The electroplating device according to claim 8, wherein the cleaning assembly is obliquely disposed at the middle of the shroud, the cleaning assembly comprising a nozzle and a connection tube, one end of the connection tube being fixed to the middle of the shroud, the nozzle being fixed at the other end of the connection tube, and the cleaning solution being sprayed out from the nozzle.

14. The electroplating device according to claim 13, wherein the nozzle is tilted with respect to the horizontal plane at a tilt angle ranging from 5° to 60°.

15. The electroplating device according to claim 13, wherein the distance between the nozzle and the vertical centerline of the substrate is in the range of 180 mm to 200 mm.

16. The electroplating device according to claim 13, wherein the vertical distance between the nozzle and the substrate is in the range of 10 mm to 30 mm in the height direction of the shroud.

17. The electroplating device according to claim 13, wherein the cleaning assembly is configured that the distance between the position where the cleaning solution sprayed by the nozzles is sprayed onto the substrate and the nozzles is adjustable.

18. The electroplating device according to claim 17, wherein the adjustable range of the distance between the position where the cleaning solution sprayed from the nozzle reaches the substrate and the nozzle is 150 mm˜180 mm.

19. The electroplating device according to claim 8, wherein the blocking ring is tilted with respect to the horizontal plane at an angle of 10°-45°.
